(19) United States
(12) Patent Application Publication
(10) Pub. No.: US 2024/0014345 A1
(43) Pub. Date: Jan. 11, 2024

(54) MULTIPLE QUANTUM WELL BAND STRUCTURES FOR LIGHT EMITTING DEVICES

(71) Applicant: John G Wasserbauer, Castro Valley, CA (US)

(72) Inventor: John G Wasserbauer, Castro Valley, CA (US)

(21) Appl. No.: 18/331,908

(22) Filed: Jun. 8, 2023

Related U.S. Application Data
(63) Continuation-in-part of application No. 16/731,722, filed on Dec. 31, 2019, now abandoned.

(51) Int. Cl. H01L 33/06; H01L 33/00

(52) U.S. Cl. CPC H01L 33/06; H01L 33/0025; H01L 2933/0083

(57) ABSTRACT

An apparatus and method for reducing the quantum confined Stark effect in polarized compound semiconductors optical gain regions is disclosed. The apparatus comprises a continuously graded multi-quantum well (MQW) band structure wherein the quantum wells (QWs) are concatenated with no quantum barriers (QBs) in between and no more than one heterojunction interface per well. An alternative, equivalent MQW band structure comprises continuously graded QWs separated by continuously graded QBs with no more than one heterojunction interface per well. In both embodiments the band structures are devoid of constant bandgap layers. Continuously graded, concatenated QWs with small perturbations layers of constant bandgap are contemplated. Non-uniform period and non-uniform bandgap range MQW structures are disclosed. Non-uniform QW/QB thickness ratio MQW structures are also considered.

### CROSS-REFERENCE TO RELATED APPLICATION

This application is a continuation-in-part of, and claims the benefit of, U.S. patent application Ser. No. 16/731,722, filed Dec. 31, 2019, of which the disclosure is incorporated herein by reference in its entirety.

### FIELD OF THE INVENTION

The invention relates to an apparatus, system, and method for reducing the quantum confined Stark effect in polarized compound semiconductors, and, more particularly, a multi-quantum well structure wherein the electron and hole wavefunctions have improved overlap.

### BACKGROUND OF THE INVENTION

Compound semiconductors have achieved great success in realizing practical optoelectronic devices, such as lasers and detectors. Compounds based on III-V elements, such as InP and GaAs, have produced optoelectronic devices that emit light from the far infrared to visible, i.e., orange, wavelengths. For short wavelengths from the green to ultraviolet, larger bandgap semiconductors, such as the III-nitride compounds, i.e., InN, GaN and AlN, have been used. Whereas the former compounds have a non-polar, zinc-blend structure, the III-nitride material system has a wurtzite lattice structure and exhibit extremely high built-in spontaneous and (strain-induced) piezoelectric fields due to the broken inversion symmetry in the uniaxial crystal structure, which leads to a severe drop in quantum efficiency at high current densities.

Light-emitting semiconductor devices typically employ heterojunctions to confine electrons and holes in a common layer of the crystal lattice called a quantum well, herein “QW”, thereby increasing the probability of radiative recombination. FIGS. 1A and 1B illustrate the effect of polarization on the energy bands of a single QW 101. In this and all subsequent figures, the growth direction is from left to right. FIG. 1A exhibits the conduction 120 and valence band 130 diagrams of a single QW 101, which comprises a layer of narrow bandgap material 200 surrounded by layers of larger bandgap 300a, 300b, also called quantum barriers, herein “QBs”. Without polarization, the conduction 120 and valence 130 bands are flat, i.e., horizontal, while the QW/QB the interfaces have stepwise, i.e., vertical, changes in the energy gap between electron and hole bands. Also shown are the electron 210a and hole 210b quantum levels and probability wavefunctions 220a, 200b, the latter being symmetric within the QW and having a high degree of overlap. Referring to FIG. 1B, under the influence of polarization a downward step in bandgap, as between layers 300a and 200, causes a negative polarization at the interface, which attracts a positive sheet charge, producing a change in slope of the band structure. The presence of the sheet charge requires that the slope of the bands on either side of the heterointerface be of opposite sign, in this case positive on the left and negative on the right. An upward step in bandgap, such as between layers 200 and 300b, does the opposite. Between the interfaces band tilting and/or bending must occur to satisfy these constraints. FIG. 1B also illustrates the effect of this band distortion on the quantum levels 210a, 210b and wavefunctions 220a, 220b; the electron 210a and hole 210b quantum levels are drawn closer to each other in energy, while the electron 220a and hole 220b wavefunctions are pushed farther apart. This is known as the quantum confined Stark effect (QCSE).

The QCSE causes a weaker carrier transition strength and longer carrier lifetimes leading to a reduction of the radiative recombination rate. The latter is undesirable because longer carrier lifetimes make it difficult to fabricate a practical laser from these materials with green to ultraviolet wavelengths. Additionally, the low probability of recombination leads to a high carrier concentration at high current densities. This is unwanted because, as the carrier density increases, a growing part of the carriers recombine through non-radiative Auger processes, causing further reduction of the quantum efficiency. This is often cited as a primary reason for the drop-off in efficiency, also known as droop, of blue LEDs at high current densities. In another example in the GaN/InGaN system, the QCSE increases with In concentration within an InGaN QW. This has been found to be the primary reason for the loss of efficiency of the III-nitride devices in green LEDs and lasers, which require high In content to reach the green spectral range. It is especially significant because only the III-N system can be used to construct devices emitting green light.

Another cause of efficiency reduction results from the poor injection efficiency and non-uniform distribution of holes where the QW shape also plays a role. In devices with the standard square QW, polarization distortion tends to cause the holes to pile up on the p-side of the device leading to a highly non-uniform distribution of carriers amongst the QWs. One proposed solution is p-doping of QW barriers where Mg-doped barriers are used to improve the hole distribution among multiple QWs (MQWs). However, in the p-type MQWs, Mg-dopants will easily diffuse into the well and consequently reduce the radiative efficiency.

Several methods of increasing the overlap of electrons and holes in III-N QWs have been proposed. The two main ideas rely on reduction of the built-in polarization through growth of either graded or staggered QWs and/or QBs, or growth on semipolar and nonpolar crystal orientations. Regarding the graded method, research has been focused on improving quantum efficiency through bandgap engineering of the QW and QB structures. Regarding the staggered method, large and cost-effective semipolar and non-polar substrates have yet to reach the market and are therefore not likely to play a major role in increasing LED efficiency for some time. The primary paths include grading of the QWs and QBs, and ultra-wide QWs exhibiting dynamic carrier effects.

Certain QW structures are known the III-N materials system. FIGS. 2A-2O give some examples of proposed, simulated, and/or experimentally tested QW shapes. For clarity, only the conduction band 120 is displayed and the valence band 130 is omitted. As shown in FIG. 1A, the valence band 130 is a vertically mirrored, horizontally flipped, scaled version thereof. Also, in FIGS. 1A-2O, the growth direction is from left to right, where the uppermost flat portions flanking the QW 200 represent the QBs 300a, 300b, and polarization effects have been omitted for clarity.

QW grading can be used to realize a large variety of shapes broadly categorized as stepped, linear, or non-linear, i.e., smooth. In all three categories the wells 200 may be symmetric or asymmetric. Note that the horizontal mirror images of asymmetric wells may be included in the list of possible profiles. Note also that various types of grading may be combined within a single quantum well 200. The most common QW 200 type is the ungraded square well, which has a single, stepped interface at each end and is given for reference in FIG. 2A. In a step graded QW 200, shown in FIG. 2B, layers of constant composition with decreasing bandgap are grown, followed by layers of constant composition with increasing bandgap. The number and thickness of layers and the size of the steps are variable, although most published or disclosed schemes use between 2 and 7 layers. Similarly, linearly graded QWs use layers of constant slope wherein the number and thickness of the layers and the slope of each layer may vary. An example of a simple, symmetric, V-shaped well is given in FIG. 2C, while asymmetric, forward and reverse linearly graded wells are represented in FIGS. 2D and 2E, respectively. Various combinations of step and linear grading are illustrated in FIGS. 2F through 2H. Two varieties of compound linear grading in a symmetric well are shown in FIGS. 2I and 2J. In FIG. 2K, a combination of compound linear grading and step grading forms an asymmetric well. Smooth grading uses layers of changing slope, i.e. curvature, to create QWs of various shapes, such as semicircular, sinewave, parabolic, elliptical or fermi function. FIGS. 2L and 2M exhibit wells with parabolic and Fermi profiles, respectively. FIG. 2N is a smooth QW with an arbitrary, but symmetric shape. Finally, FIG. 2O depicts a combination sinewave and linearly graded QW.

In a conventional MQW structure each well is separated from a neighboring well, and often the carrier injection layers, by a QB. In this context, a QW 200 refers to one or more layers with at least one layer comprising the smallest bandgap of the MQW structure and with the energy bands of all other QW layers monotonically increasing in bandgap. A QB 300 in this context refers to one or more layers with at least one layer comprising the largest bandgap of the MQW structure and with the energy bands of all other layers monotonically decreasing in bandgap. At the QW/QB interface, the energy bands may have one of three characteristics: there may be a step 160, as in FIG. 2B, there may be a kink 161, as in FIG. 2C, or the energy bands on either side of the interface may be tangent to each other, as in FIG. 2M.

Similar to the case of QWs 200, certain QB structures 300 are known in the III-N materials system. FIGS. 3A-3I give some examples of proposed, simulated, and/or experimentally-tested QB shapes 300. For clarity, only the conduction band 120 is displayed in FIGS. 3A-3I, the valence band 130 being omitted, it being understood that the valence band 130 is a vertically mirrored, horizontally flipped, scaled version thereof, as shown in FIG. 1A. Also in FIGS. 3A-3I, the growth direction is from left to right, the lowermost flat portions flanking the QB 300 represent the QWs 200a-b, and polarization effects have been omitted for clarity.

The most common QB 300 type is the ungraded square barrier, which has a single, stepped interface at each end as illustrated in FIG. 3A. QB 300 grading can be used to realize a large variety of shapes broadly categorized as stepped, linear, or non-linear, i.e., smooth. In all three categories the barriers may be symmetric or asymmetric. For asymmetric barriers, the grading in the growth direction may be forward or reverse, corresponding to a generally increasing or decreasing bandgap, respectively. Note that the horizontal mirror images of asymmetric QBs may be included in the list of possible profiles. Note also that various types of grading may be combined within a single QB.

In a step graded QB 300, as illustrated in e.g., FIG. 3A, layers of constant composition with increasing and/or decreasing bandgap are grown. FIG. 3B illustrates the example of a reverse, asymmetric step-graded barrier. The number and thickness of layers and the size of the steps may be variable, although most known step gradings use between 1 and 3 layers. Analogous to the QW 200 case, linearly graded QBs 300 use layers of constant slope, wherein the number and thickness of the layers and the slope of each layer may vary. An example of a simple, symmetric, inverted V-shaped barrier is given in FIG. 3C, while asymmetric, forward and reverse linearly graded barriers are represented in FIGS. 3D and 3E, respectively. Various combinations of step and linear grading are illustrated in FIGS. 3F through 3H. Smooth grading uses one or more layers of changing slope, i.e., curvature, to create QBs 300 of various shapes, such as semicircular, sinewave, parabolic, elliptical or fermi function. FIG. 3I illustrates a sinewave graded QB 300.

From the examples of FIGS. 2A-3I, one skilled in the art will appreciate that a variety of MQW structures, e.g., multiple QWs 200, may be realized by combining the various ungraded and/or graded QW 200 and QB 300 profiles. However, when polarization effects are incorporated, some aspects of these structures present disadvantages. First and foremost, a step in the energy bands adds strain-induced polarization to the already present spontaneous polarization at the heterointerface. A step reduction in the bandgap results in uncompensated negative charges that attract holes forming a positive sheet charge at the interface. Conversely, a step increase in the bandgap results in uncompensated positive charges that attract free electrons forming a negative sheet charge at the interface. Any constant bandgap energy bands between such opposing sheet charges will be tilted in proportion to the area density of the sheet charges, creating an internal electric field, as shown in FIG. 1B. A similar, but less pronounced effect occurs with the QBs 300, which are conventionally 5 to 10 times thicker than the QWs 200. Since the carrier wavefunctions penetrate the barriers, an asymmetry in the barriers will also shift the wavefunctions in opposite directions. Secondly, a constant bandgap energy band will be subject to bending not only by step-induced sheet charges, but also by kink or curvature-induced volume charges analogous to the intrinsic region of a p-i-n diode. Step heterojunctions and thick layers of constant bandgap are thus at the root of the QCSE in polarized semiconductors.

There exists a long-felt need to mitigate or eliminate the deleterious effects of band tilting on the carrier wavefunction overlap in a light-generating MQW band structure.

There also exists a long-felt need to improve the carrier distribution uniformity across QWs in a light-generating MQW band structure.

### SUMMARY OF INVENTION

The invention provides a system for reducing polarization effects, primarily the quantum confined Stark effect (QCSE), in a compound semiconductor multi-quantum well optical gain structure. This is achieved by continuously graded band structures wherein layers of constant bandgap and step discontinuities are minimized or eliminated. In one embodiment a MQW structure comprises continuously graded QWs with no QBs and with no discontinuities at the QW/QW interface. In another embodiment a MQW structure comprises continuously graded QWs and continuously graded QBs with no discontinuities at the QW/QB interface. In another embodiment a MQW structure comprises continuously graded QWs with no QBs and a discontinuity at the QW/QW interface. In another embodiment a MQW structure comprises continuously graded QWs with no QBs and further comprising perturbation layers having constant bandgap. Barrier-free MQW structures with non-uniform QW/QB thickness and/or non-uniform minimum and/or maximum bandgap are also contemplated.

Other desirable features and characteristics will become apparent from the subsequent detailed description, the drawings, the abstract, and the claims, when considered in view of this summary

### BRIEF DESCRIPTION OF THE DRAWINGS

In the drawings, like numerals describe like components throughout the several views:

FIG. 1A illustrates a band diagram of a QW without polarization effects, according to the prior art;

FIG. 1B illustrates a band diagram of a QW with polarization effects, according to the prior art;

FIG. 2A illustrates a band diagram of an ungraded, square QW without polarization effects, according to the prior art;

FIG. 2B illustrates a band diagram of a step-graded QW without polarization effects, according to the prior art;

FIG. 2C illustrates a band diagram of a symmetric, V-shaped, linearly graded QW without polarization effects, according to the prior art;

FIG. 2D illustrates a band diagram of an asymmetric, V-shaped, forward linearly graded QW without polarization effects, according to the prior art;

FIG. 2E illustrates a band diagram of an asymmetric, V-shaped, reverse linearly graded QW without polarization effects, according to the prior art;

FIG. 2F illustrates a band diagram of an asymmetric, V-shaped, forward, partially linearly graded QW without polarization effects, according to the prior art;

FIG. 2G illustrates a band diagram of an asymmetric, V-shaped, reverse, partially linearly graded QW without polarization effects, according to the prior art;

FIG. 2H illustrates a band diagram of an asymmetric, forward, partially linearly graded QW without polarization effects, according to the prior art;

FIG. 2I illustrates a band diagram of a symmetric, V-shaped, compound linearly graded QW with negative kinks and without polarization effects, according to the prior art;

FIG. 2J illustrates a band diagram of a symmetric, V-shaped, compound linearly graded QW with positive kinks and without polarization effects, according to the prior art;

FIG. 2K illustrates a band diagram of an asymmetric, V-shaped, compound linear and step graded QW with positive kinks and without polarization effects, according to the prior art;

FIG. 2L illustrates a band diagram of a symmetric, smooth, parabolic-shaped, non-linearly graded QW without polarization effects, according to the prior art;

FIG. 2M illustrates a band diagram of a symmetric, smooth, Fermi function-shaped, non-linearly graded QW without polarization effects, according to the prior art;

FIG. 2N illustrates a band diagram of a symmetric, smooth, non-linearly graded QW without polarization effects, according to the prior art;

FIG. 2N illustrates a band diagram of an asymmetric, non-linearly and linearly graded QW without polarization effects, according to the prior art;

FIG. 3A illustrates a band diagram of an ungraded, square QB without polarization effects, according to the prior art;

FIG. 3B illustrates a band diagram of an step-graded QB without polarization effects, according to the prior art;

FIG. 3C illustrates a band diagram of a symmetric, V-shaped, linearly graded QB with negative kinks without polarization effects, according to the prior art;

FIG. 3D illustrates a band diagram of an asymmetric, V-shaped, forward linearly graded QB without polarization effects, according to the prior art;

FIG. 3E illustrates a band diagram of an asymmetric, V-shaped, reverse linearly graded QB without polarization effects, according to the prior art;

FIG. 3F illustrates a band diagram of an asymmetric, reverse, partially linearly graded QB without polarization effects, according to the prior art;

FIG. 3G illustrates a band diagram of an asymmetric, forward, partially linearly and step graded QB without polarization effects, according to the prior art;

FIG. 3H illustrates a band diagram of a symmetric, partially linearly and step graded QB without polarization effects, according to the prior art;

FIG. 3I illustrates a band diagram of a symmetric, non-linearly (sinewave) graded QB without polarization effects, according to the prior art;

FIG. 4A illustrates an interface conduction band discontinuity in the form of a heterojunction without polarization effects, according to the prior art;

FIG. 4B illustrates a polarization induced sheet charge at a downward step conduction band discontinuity, according to the prior art;

FIG. 4C illustrates an interface conduction band discontinuity in the form of a heterojunction with polarization effects, according to the prior art;

FIG. 5A illustrates a downward linearly graded conduction band without polarization effects, according to the prior art;

FIG. 5B illustrates a polarization induced, uniform space charge within a layer having a downward linearly graded bandgap, according to the prior art;

FIG. 5C illustrates a downward linearly graded conduction band with polarization effects, according to the prior art;

FIG. 6A illustrates a downward non-linearly graded conduction band without polarization effects, according to the prior art;

FIG. 6B illustrates a polarization induced, non-uniform space charge within a layer having a downward non-linearly graded bandgap, according to the prior art;

FIG. 6C illustrates a downward non-linearly graded conduction band with polarization effects, according to the prior art;

FIG. 7A illustrates a concatenated, symmetric, V-shaped, linearly graded, MQW band structure without polarization effects, according an embodiment of to the present invention;

FIG. 7B illustrates a concatenated, symmetric, V-shaped, linearly graded MQW band structure with polarization effects, according to an embodiment of the present invention;

FIG. 8A illustrates a concatenated, symmetric, Y-shaped, non-linearly graded MQW band structure without polarization effects, according to an embodiment of the present invention;

FIG. 8B illustrates a concatenated, symmetric, Y-shaped, non-linearly graded MQW band structure with polarization effects, according to an embodiment of the present invention;

FIG. 9A illustrates a concatenated, symmetric, smooth-shaped, non-linearly graded MQW band structure without polarization effects, according to an embodiment of the present invention;

FIG. 9B illustrates a concatenated, symmetric, smooth-shaped, non-linearly graded MQW band structure with polarization effects, according to an embodiment of the present invention;

FIG. 10A illustrates a concatenated, asymmetric, sawtooth-shaped, forward, linearly graded MQW band structure without polarization effects, according to an embodiment of the present invention;

FIG. 10B illustrates a concatenated, symmetric, sawtooth-shaped, forward, linearly graded MQW band structure with polarization effects, according to an embodiment of the present invention;

FIG. 11A illustrates a concatenated, asymmetric, sawtooth-shaped, forward, non-linearly graded MQW band structure without polarization effects, according to an embodiment of the present invention;

FIG. 11B illustrates a concatenated, symmetric, sawtooth-shaped, forward, non-linearly graded MQW band structure with polarization effects, according to an embodiment of the present invention;

FIG. 12A illustrates a concatenated, asymmetric, sawtooth-shaped, reverse, non-linearly graded MQW band structure without polarization effects, according to an embodiment of the present invention;

FIG. 12B illustrates a concatenated, asymmetric, sawtooth-shaped, reverse, non-linearly graded MQW band structure with polarization effects, according to an embodiment of the present invention;

FIG. 13A illustrates a symmetric, V-shaped, linearly graded QW and symmetric, V-shaped, linearly graded QB in a MQW band structure without polarization effects, according to an embodiment of the present invention;

FIG. 13B illustrates a symmetric, smooth-shaped, non-linearly graded QW and symmetric, smooth-shaped, non-linearly graded QB in a MQW band structure without polarization effects, according to an embodiment of the present invention;

FIG. 13C illustrates a symmetric, smooth-shaped, non-linearly graded QW and asymmetric, non-linearly and linearly graded QB in a MQW band structure without polarization effects, according to an embodiment of the present invention;

FIG. 14A illustrates a symmetric, V-shaped, six layer, linearly graded QW in a MQW band structure without polarization effects, according to the present invention;

FIG. 14B illustrates a symmetric, V-shaped, four layer, linearly graded QW and symmetric, inverted V-shaped, two layer, linearly graded QB in a MQW band structure without polarization effects, according to the present invention;

FIG. 14C illustrates a symmetric, V-shaped, two layer, linearly graded QW and symmetric, inverted V-shaped, four layer, linearly graded QB in a MQW band structure without polarization effects, according to the present invention;

FIG. 14D illustrates an asymmetric, V-shaped, three layer, linearly graded QW and asymmetric, inverted V-shaped, three layer, linearly graded QB in a MQW band structure without polarization effects, according to the present invention;

FIG. 15A illustrates an asymmetric, sawtooth-shaped, three layer, linearly graded QW in a MQW band structure without polarization effects, according to the present invention;

FIG. 15B illustrates an asymmetric, sawtooth-shaped, two layer, linearly graded QW and asymmetric, sawtooth-shaped, single layer, linearly graded QB in a MQW band structure without polarization effects, according to the present invention;

FIG. 15C illustrates an asymmetric, sawtooth-shaped, single layer, linearly graded QW and asymmetric, sawtooth-shaped, two layer, linearly graded QB in a MQW band structure without polarization effects, according to the present invention;

FIG. 15D illustrates an asymmetric, single layer, linearly graded QW and asymmetric, single layer, linearly graded QB in a MQW band structure without polarization effects, according to the prior art;

FIG. 16A illustrates a symmetric, V-shaped, seven layer, linearly graded QW with constant bandgap perturbations without polarization effects, according to the present invention; and

FIG. 16B illustrates an asymmetric, V-shaped, six layer, linearly graded QW with constant bandgap perturbations and a small, stepped bandgap interface without polarization effects, according to the present invention.

### DETAILED DESCRIPTION OF THE EMBODIMENTS

Non-limiting embodiments of the invention will be described below with reference to the accompanying drawings, wherein like reference numerals represent like elements throughout. While the invention has been described in detail with respect to the preferred embodiments thereof, it will be appreciated that upon reading and understanding of the foregoing, certain variations to the preferred embodiments will become apparent, which variations are nonetheless within the spirit and scope of the invention. The drawings featured in the figures are provided for the purposes of illustrating some embodiments of the invention and are not to be considered as limitation thereto. The drawings of band structures, carrier distributions, quantum levels, and wavefunctions are qualitative in nature and are intended to illustrate general features of unpolarized and polarized layers, interfaces and MQW structures. The terms “a” or “an”, as used herein, are defined as one or as more than one. The term “plurality”, as used herein, is defined as two or as more than two. The term “another”, as used herein, is defined as at least a second or more. The terms “including” and/or “having”, as used herein, are defined as comprising (i.e., open language). The term “coupled”, as used herein, is defined as connected, although not necessarily directly, and not necessarily mechanically.

Reference throughout this document to “some embodiments”, “one embodiment”, “certain embodiments”, and “an embodiment” or similar terms means that a particular feature, structure, or characteristic described in connection with the embodiment is included in at least one embodiment of the present invention. Thus, the appearances of such phrases or in various places throughout this specification are not necessarily all referring to the same embodiment. Furthermore, the particular features, structures, or characteristics may be combined in any suitable manner in one or more embodiments without limitation.

The term “or” as used herein is to be interpreted as an inclusive or meaning any one or any combination. Therefore, “A, B or C” means any of the following: “A; B; C; A and B; A and C; B and C; A, B and C”. An exception to this definition will occur only when a combination of elements, functions, steps or acts are in some way inherently mutually exclusive.

The term “means” preceding a present participle of an operation indicates a desired function for which there is one or more embodiments, i.e., one or more methods, devices, or apparatuses for achieving the desired function and that one skilled in the art could select from these or their equivalent in view of the disclosure herein and use of the term “means” is not intended to be limiting.

The term “strictly increasing” (also called “monotone increasing”) is defined as always increasing; never remaining constant or decreasing. The term “strictly decreasing” (also called “monotone decreasing”) is defined as always decreasing; never remaining constant or increasing. The term “monotonically increasing” is defined as entirely non-decreasing. The term “monotonically decreasing” is defined as entirely non-increasing. All four definitions allow for steps in the form of vertical portions in the direction of inclination.

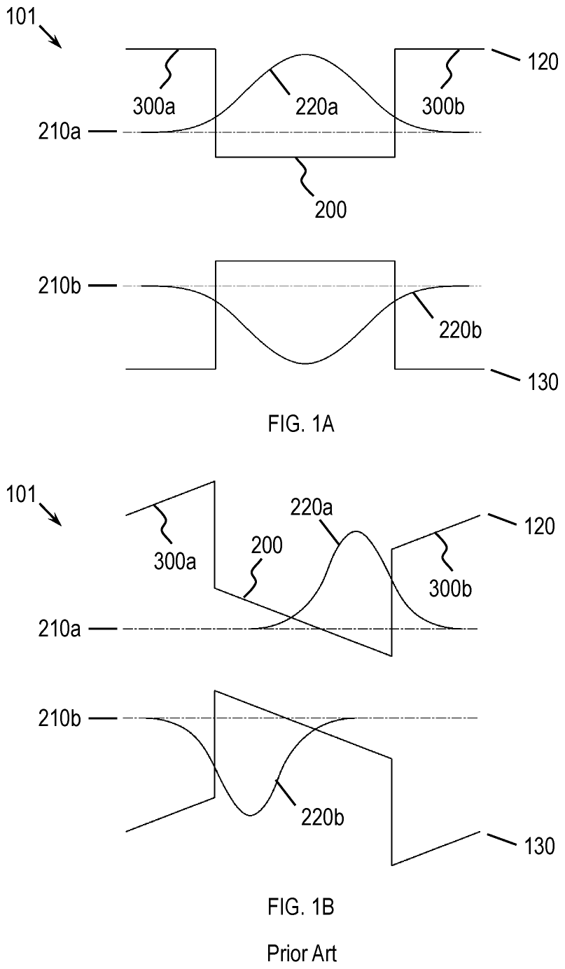

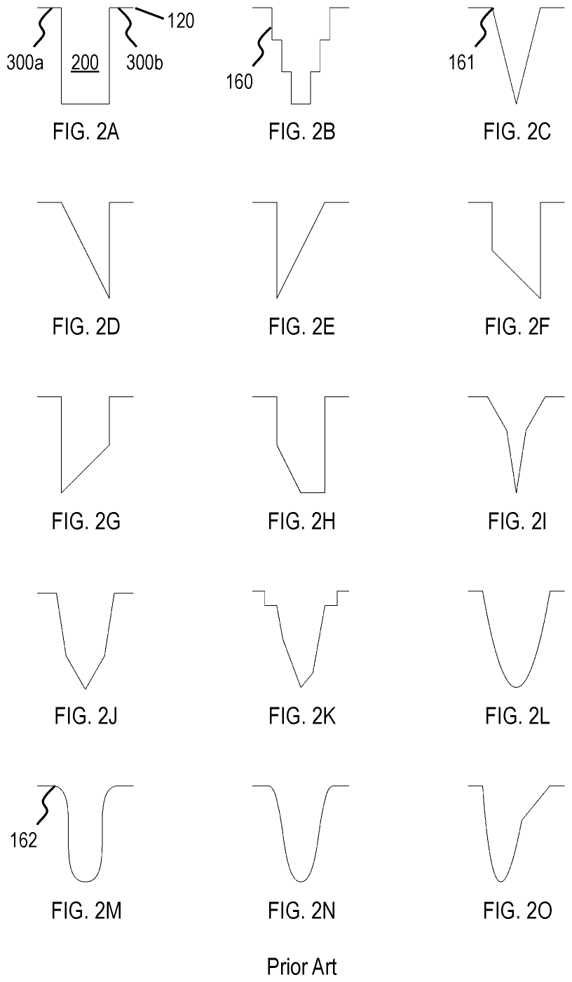

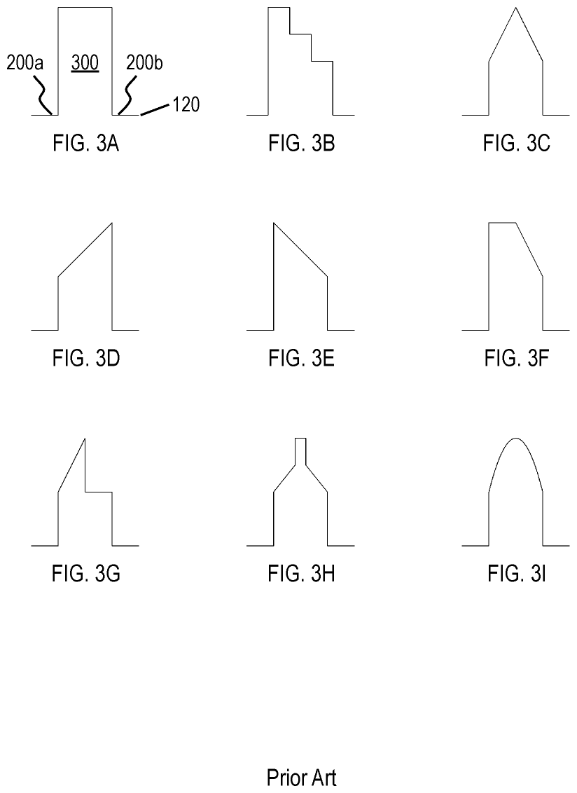

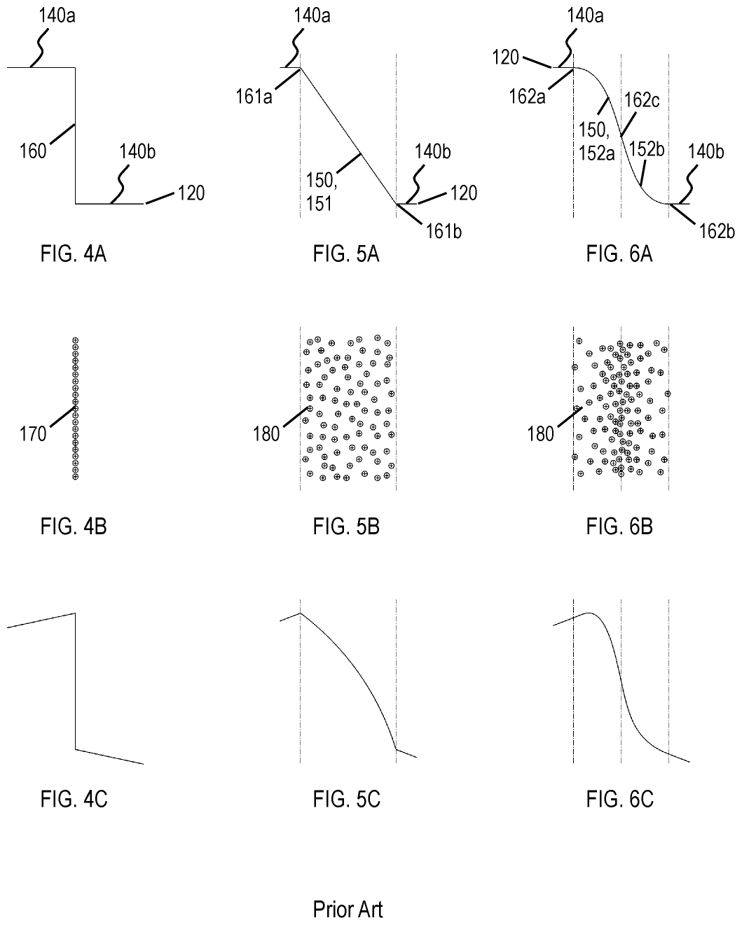

FIGS. 1A-3I illustrate certain conduction bands corresponding to the various known layers and interfaces in unpolarized and polarized semiconductors. As will be elaborated upon in the following paragraphs, a layer may refer to two interfaces separated by a thickness. Between the two interfaces, the composition of the layer may be constant or graded. For graded layers the grading may be either linear or non-linear, i.e., smooth. Examples of layer and interface types are given in FIGS. 4A-6C where vertical solid or dashed lines indicate the interfaces and the space between the interfaces correspond to the layers.

At an interface, the energy bands may be described as stepped 160, kinked 161, or tangent 162, wherein a tangent 162 energy band implies that at least one of the adjoining layers must be non-linearly graded. If both adjoining layers are non-linearly graded, a tangent interface 162 may form a maximum or minimum. For example, a step 160, shown in FIG. 4A, refers to an abrupt change in composition, or an abrupt change in bandgap, and also may be referred to as a heterojunction or heterointerface. A heterojunction is a discontinuous interface. A kink 161a, 161b, shown in FIG. 5A for example, refers to an abrupt change in slope. A tangent 162a, 162b, as exemplified in FIG. 6A for example, refers to an abrupt change in curvature, wherein the slope is continuous across the interface. Both kinked 161 and tangent 162 interfaces are continuous interfaces. Tangent interfaces 162a, 162b may have a flat 140a, 140b or linearly graded layer on one side. Tangent interfaces 162c may alternatively have a smoothly graded layer on both sides of the interface and be identified by a change in the sign of the curvature, e.g., from positive to negative or vice versa (also known as an inflection point). Yet alternatively, a tangent interface 162 may have smoothly graded layers with the same sign of curvature on both sides of the interface and be identified by a maximum or minimum between them. Note that a step 160 may be combined with a kink 161 or a tangent 162 interface, giving rise to a step-kink or step-tangent interface. A kink-tangent interface is possible and implies smoothly graded layers of different curvature magnitude on either side of the interface. A kink-step-tangent interface is also possible. In summary, a layer must be defined by two interfaces, each interface identifiable by a step 160, kink 161 or tangent 162, or a valid combination thereof.

Within a layer, the bandgap may be ungraded 140, i.e. constant, or graded 150. Graded bandgaps 150 may be linearly graded 151, or non-linearly graded 152, i.e., smoothly graded. A smoothly graded energy band refers to an energy band that has no constant, kinked, or stepped sections. An example of a constant bandgap layer is given in FIG. 4A where two layers of constant, but unequal, bandgap 140a, 140b adjoin forming a heterointerface. An example of a linearly graded bandgap layer 151 is shown in FIG. 5A where is flanked by layers of constant bandgap 140a, 140b. Finally, an example of smoothly graded layers may be found in FIGS. 6A-6C, where two parabolically graded layers of opposite sign share a tangent, i.e., an inflection point, where interfaces are sandwiched between layers of constant bandgap, i.e., flat portions. While in the common vernacular a single, smoothly graded layer may have both signs of band curvature, or alternatively a single sign of curvature but also a including a local minimum or maximum, herein the convention is that only one sign of slope or one sign of curvature with no changes in inclination may exist within a layer. This convention removes some ambiguity in the definition of a layer. To summarize, FIG. 4A displays two layers and one interface, FIG. 5A shows, three layers and two interfaces, and FIG. 6A exhibits four identifiable layers and three interfaces.

In order to understand the origins of the band distortions in polarized semiconductors, it is necessary to know something of the strain-induced polarization fields. By way of example, in the InGaN/GaN system used for QW/QB structures in blue LEDs, growth typically takes place on the N-polar c-plane of the Wurtzite lattice. Increasing the In mole fraction increases the lattice constant, inducing compressive stress, elongation of the lattice along the Miller-index direction, and uncompensated negative polarization. The negative polarization is compensated by positive charge carriers, i.e., holes. The amount of polarization, and attendant compensation, depends on both the magnitude and sign of the In compositional changes. FIGS. 4B, 5B, and 6B illustrate the distribution of free holes for the abrupt interface and graded layers of FIGS. 4A, and 6A, respectively. In the step junction 160 of FIG. 4A, all of the strain-induced polarization is concentrated in the plane of the interface. As a result, all of the free carriers, i.e., holes, are also located at the interface, as shown in FIG. 4B, thereby forming a sheet charge 170 and causing the Fermi level to dip below the valence band. To accommodate this change, the bands on the high-bandgap side—i.e., left side—tilt up, while the bands on the low-bandgap side—i.e., right side—tilt down, as shown in FIG. 4C. In the linearly graded bandgap layer 151 with kinked interfaces 161a, 161b, shown in FIG. 5A, the sheet charge 170 has been spread out into a uniform space charge 180, as illustrated in FIG. 5B. At the interfaces, shown in FIG. 5C, the bands tilt as in the previous example, albeit to a lesser degree due to the lower carrier concentration, resulting from the spreading of the sheet charge. For the smoothly graded bandgap layers 152a, 152b with tangent interfaces 162a-c of FIG. 6A, a hole space charge 180 with a concentration gradient exists within the layers 152a, 152b, starting at the left interface 162a with a sparse 3D hole concentration, increasing towards the highly sloped interface 162c between the smoothly graded layers 152a, 152b, and decreasing once again toward the opposing tangent interface 162b. The band bending in this case follows a similar trajectory, shown in FIG. 6C, with a small amount of curvature added to the left side of the graded layers, a large amount of curvature added to the middle, and a small amount of curvature added to the right side of the graded layers 152a, 152b. Note that the tilting of the flat band portions of the energy bands 140a, 140b occurs in all three cases implies a sheet, volume or gradient negative charge (not visible) off to the left and right of the constant bandgap layers whereupon the electric field may terminate. It is also important to note that such flat band portions of a polarized MQW structure will invariably be tilted in this way, often contributing to the QCSE in the quantum confined regions. For this reason, one of the goals of the present invention is to minimize or eliminate such flat portions from the band structure 120. The previous example also applies to the GaN/AlGaN materials system wherein the sign of the strain is opposite that of the GaN/InGaN system, and other systems.

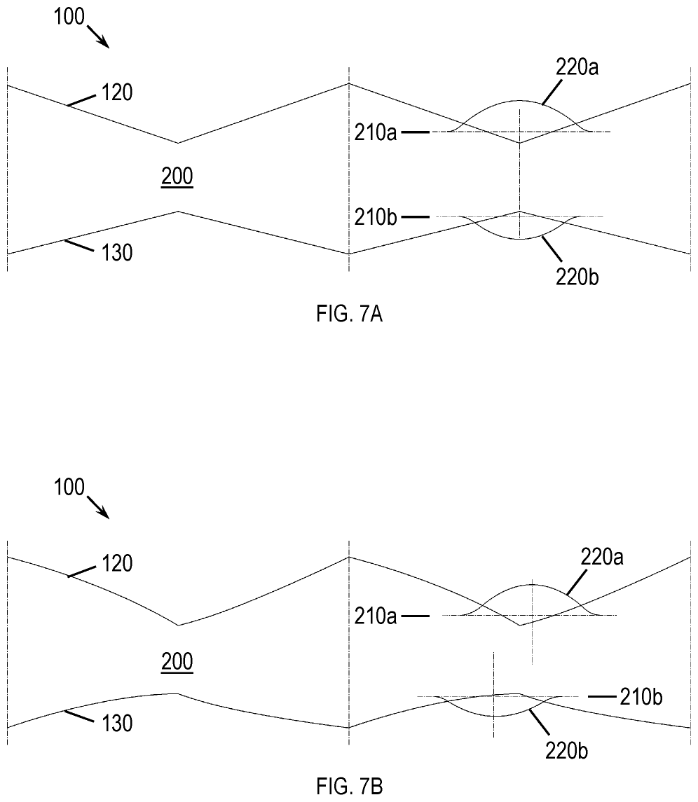

In an exemplary embodiment FIGS. 7A and 7B show the energy bands of a concatenated, linearly graded, V-shaped MQW structure 100, according to the present invention. FIG. 7A shows the conduction 120 and valence 130 bands of the unpolarized wells, which are symmetric about a bandgap minimum in the center of the well 200. Alternatively, the linear downward and upward grading may comprise multiple layers of different slope and may be asymmetric and alternatives thereto are non-limiting. The first quantum levels 210a, 210b and wavefunctions 220a, 220b for electrons and holes are also shown and can be seen in FIG. 7A to have excellent overlap. The overlap is less than complete, however, because the effective mass of the holes is greater than that of the electrons. Thus, the hole quantum level 210b is closer to the bottom of the well 200 than the electron quantum level 210a and has an effectively narrower well. Also, the evanescent portion of the hole wavefunction 220b penetrates the V-well less than the electron wavefunction 220a, resulting in a further narrowing of the hole wavefunction 220b relative to the electron wavefunction 220a. These effects are counterbalanced by the fact that the hole band offset is less than the electron band offset, causing the slope of the valence band 130 to be shallower than the slope of the conduction band 120, effectively widening the well for holes relative to electrons. The shallower slope of the valence band 130 allows the hole wavefunction 220b to spread out relative to the electron wavefunction 220a, improving the overlap between the two.

FIG. 7B shows the V-wells 100 wherein polarization effects have been incorporated, according to an embodiment of the present invention. The downward linear grading of the left side of the well 200 causes a positive space charge, inducing a negative curvature in the energy bands 120, 130. Conversely, the upward linear grading of the right side of the well 200 causes a negative space charge, inducing a positive curvature in the energy bands 120, 130. The result appears as a tilting of the bottom of the well with conduction 120 and valence 130 bands tilting in opposite directions. The first quantum levels 210a, 210b and wavefunctions 220a, 220b for electrons and holes are also shown and can be seen to be shifted in opposite directions causing the magnitude of the overlap integral to be reduced. Furthermore, the shape of the wells 200 has changed, effectively becoming wider for both electrons and holes. The quantum levels in wider wells sit closer to the band edge causing a red shift in the emission wavelength. Thus, the QCSE remains in effect for this band structure.

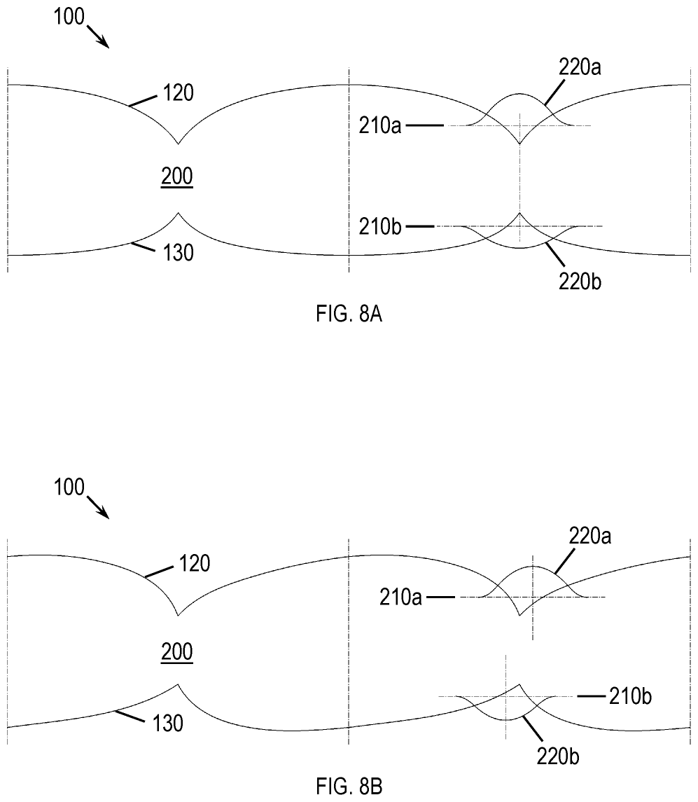

In an exemplary embodiment FIGS. 8A and 8B show the energy bands of a concatenated, linearly graded, Y-shaped MQW structure 100, according to the present invention. FIG. 8A shows the conduction 120 and valence 130 bands of the unpolarized wells, which are symmetric about a bandgap minimum in the center of the well 200. Alternatively, the non-linear downward and upward grading may comprise multiple layers of different curvature and may be asymmetric, and alternatives thereto are non-limiting. The first quantum levels 210a, 210b and wavefunctions 220a, 220b for electrons and holes are also shown and can be seen to have excellent overlap. The overlap is less than complete, however, for similar reasons as those given with respect to FIG. 7A.

FIG. 8B shows the Y-wells 100 wherein polarization effects have been incorporated, according to one or more embodiments of the present invention. The downward non-linear grading of the left side of the well 200 causes a non-uniform, positive space charge, inducing a negative curvature in the energy bands 120, 130. Conversely, the upward non-linear grading of the right side of the well 200 causes a non-uniform, negative space charge, inducing a positive curvature in the energy bands 120, 130. The magnitude of the negative and positive changes in curvature varies with the slope of the grading, as previously discussed. The result appears as a tilting of the bottom of the well with conduction 120 and valence 130 bands tilting in opposite directions. The first quantum levels 210a, 210b and wavefunctions 220a, 220b for electrons and holes are shifted in opposite directions, causing the magnitude of the overlap integral to be reduced. Furthermore, the shape of the wells 200 has changed, effectively becoming wider for both electrons and holes. The quantum levels in wider wells closer to the band edge causing a red shift in the emission wavelength. Thus, the QCSE remains in effect for this band structure.

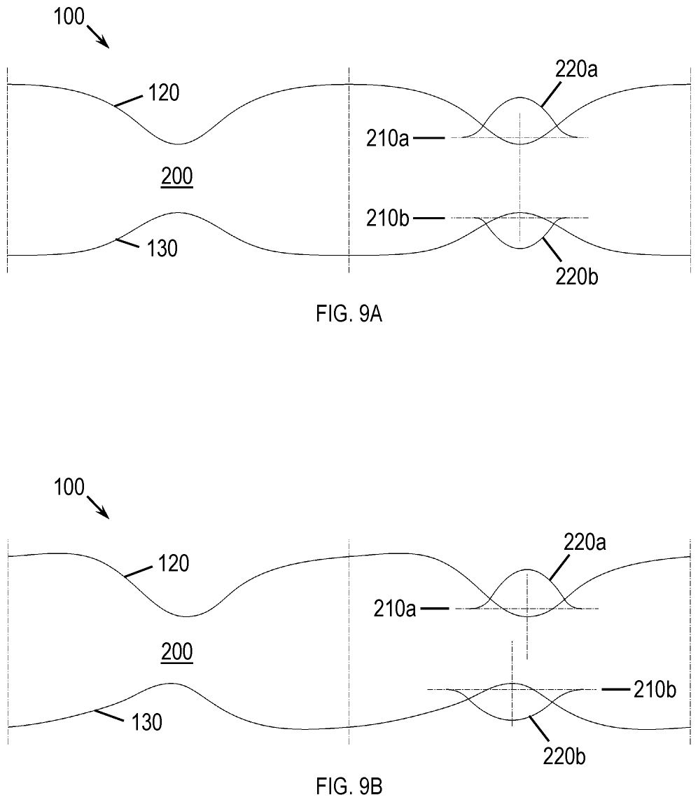

In an exemplary embodiment FIGS. 9A and 9B show the energy bands of a concatenated, non-linearly graded, smooth-shaped MQW structure 100, according to the present invention. FIG. 9A shows the conduction 120 and valence 130 bands of the unpolarized wells 200, which are symmetric about a bandgap minimum in the center of the well 200. Alternatively, the non-linear downward and upward grading may comprise multiple layers of different curvature and may be asymmetric, and alternatives thereto are non-limiting. The first quantum levels 210a, 210b and wavefunctions 220a, 220b for electrons and holes are also shown and can be seen to have advantageous overlap. The overlap is less than complete, however, for similar reasons as those given with respect to FIG. 7A.

FIG. 9B shows the smooth wells 100 wherein polarization effects have been incorporated, according to the present invention. The downward non-linear grading of the left side of the well 200 causes a non-uniform, positive space charge, inducing a negative curvature in the energy bands 120, 130. Conversely, the upward non-linear grading of the right side of the well 200 causes a negative space charge, inducing a positive curvature in the energy bands 120, 130. The magnitude of the negative and positive changes in curvature varies with the slope of the grading, as previously discussed. The result appears as a shifting of the bottom of the well 200 with conduction 120 and valence 130 bands shifting in opposite directions. The first quantum levels 210a, 210b and wavefunctions 220a, 220b for electrons and holes are also shown and can be seen to be shifted in opposite directions causing the magnitude of the overlap integral to be reduced. However, unlike the V- and Y-shaped wells 200, the shape of the wells 200 remains substantially the same and the quantum levels 210a, 210b sit at approximately the same distance from the band edges. Thus, the QCSE may be at least partially reduced for this band structure.

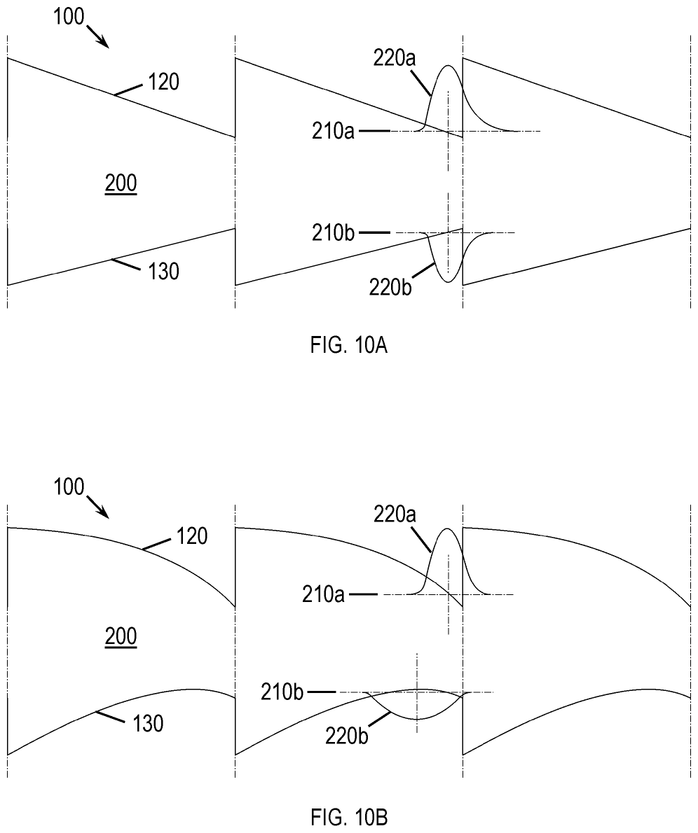

Concatenated QWs 200 in a MQW band structure 100 may have a single heterointerface between them, as contemplated in one or more embodiments according to the present invention. In an exemplary embodiment FIGS. 10A and 10B show the energy bands of a concatenated, linearly graded, asymmetric, sawtooth-shaped MQW structure 100. FIG. 10A shows the conduction 120 and valence 130 bands of the unpolarized wells 200, which are asymmetric about a bandgap minimum at the right edge of the well 200. Alternatively, the linear downward grading may comprise multiple layers of different slope and/or portions of non-linear grading, and alternatives thereto are non-limiting. Yet alternatively, one or more linear upward graded layers may be used to form a reverse sawtooth. The first quantum levels 210a, 210b and wavefunctions 220a, 220b for electrons and holes are also shown and can be seen to have excellent overlap. The overlap is less than complete, however, for similar reasons as those given with respect to FIG. 7A.

FIG. 10B shows the linear, sawtooth-shaped QWs 200 wherein polarization effects have been incorporated, in accordance with the present invention. The downward linear grading of the left side of the well 200 causes a uniform, positive space charge, inducing a negative curvature in the energy bands 120, 130. Conversely, the upward step grading of the right side of the well 200 causes a negative sheet charge, inducing a more positive kink in the energy bands 120, 130. The magnitude of the negative change in curvature varies with the slope of the grading, as previously discussed, while the magnitude of the positive kink is proportional to the magnitude of the bandgap step. Advantageously, the right side of the QW 200 formed by the step heterojunction does not tilt, thereby reducing the effect of the deformation of the energy bands 120, 130 on the wavefunction 220a, 220b shift. Nonetheless, the first quantum levels 210a, 210b and wavefunctions for electrons 220a and holes 220b are also shown and can be seen to be shifted in opposite directions, causing the magnitude of the overlap integral to be reduced. The conduction band 130 curvature becomes more negative causing the notch to become narrower. As a result, the conduction band quantum level 210a rises in energy, and the peak of the wavefunction 220a moves toward the nearest QW 200 interface. The valence band 130 curvature also becomes more negative, causing the notch to flatten out and form a minimum further away from the nearest QW 200 interface. As a result, the valence band quantum level 210b increases in energy moving closer to the conduction band 120. Overall, however, the distance between the quantum levels 210a, 220b stays substantially the same or increases slightly, giving rise to a blue shift in the emission wavelength. Thus, the QCSE may be partially reduced for this band structure. Depending on the grading used, the overlap between electron 220a and hole 220b wavefunctions may be reduced. To mitigate this effect, a sawtooth profile with non-linear grading may be used.

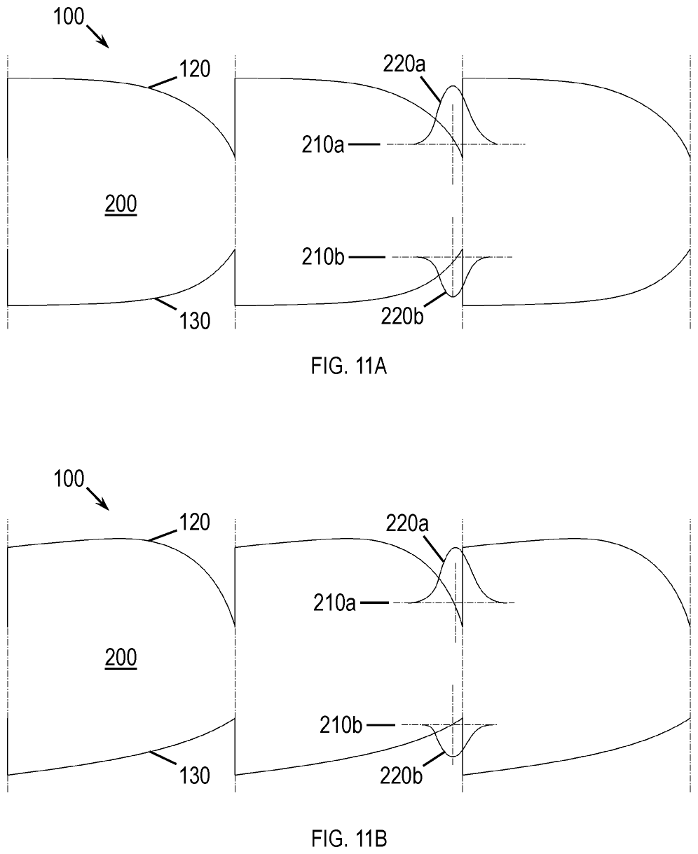

In an exemplary embodiment FIGS. 11A and 11B show the energy bands of a concatenated, non-linearly graded, asymmetric, sawtooth-shaped MQW structure 100, according to the present invention. FIG. 11A shows the conduction 120 and valence 130 bands of the unpolarized wells 200, which are asymmetric about a bandgap minimum at the right edge of each well 200. Alternatively, the non-linear downward grading may comprise multiple layers of different curvature and/or portions of linear grading, and alternatives thereto are non-limiting. The first quantum levels 210a, 210b and wavefunctions 220a, 220b for electrons and holes are also shown and can be seen to have excellent overlap. The overlap is less than complete, however, for similar reasons given with respect to FIG. 7A.

FIG. 11B shows the non-linear, sawtooth-shaped QWs 200 wherein polarization effects have been incorporated, according to the present invention. The downward non-linear grading of the left side of the well 200 causes a non-uniform, positive space charge, inducing a more negative curvature in the energy bands 120, 130. Conversely, the upward step grading of the right side of the well 200 causes a negative sheet charge, inducing a more positive kink in the energy bands 120, 130. The magnitude of the negative change in curvature varies with the slope of the grading, as previously discussed, while the magnitude of the positive kink is proportional to the magnitude of the step. Advantageously, the right side of the QW 200 formed by the step heterojunction does not tilt, thereby reducing the effect of the deformation of the energy bands 120, 130 on the wavefunction 220a, 220b shift. Nonetheless, the first quantum levels 210a, 210b and wavefunctions for electrons 220a and holes 220b are also shown and can be seen to be shifted in opposite directions causing the magnitude of the overlap to be reduced. The conduction band 130 curvature becomes more negative causing the notch to become narrower. As a result, the conduction band quantum level 210a rises in energy and the peak of the wavefunction 220a moves toward the nearest QW 200 interface. The valence band 130 curvature also becomes more negative causing the notch to flatten out and form a minimum further away from the nearest QW 200 interface. As a result, the valence band quantum level 210b increases in energy moving closer to the conduction band 120. Overall, however, the distance between the quantum levels 210a, 210b stays substantially the same or increases slightly, giving rise to a blue shift in the emission wavelength. Depending on the grading used, the overlap between electron 220a and hole 220b wavefunctions may remain substantially the same. Thus, the QCSE may be reduced for this band structure.

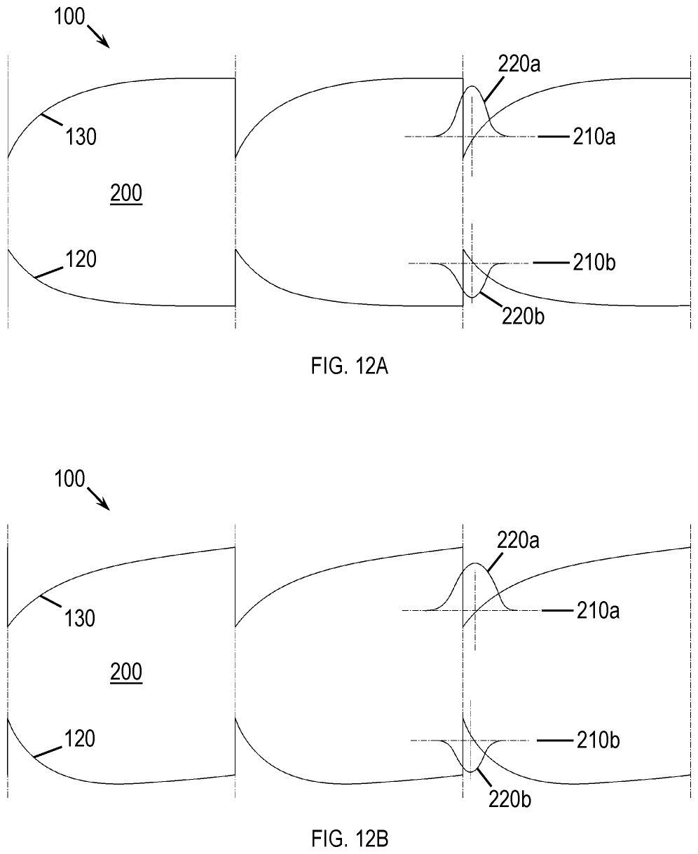

In an exemplary embodiment FIGS. 12A and 12B show the energy bands of a concatenated, non-linearly graded, asymmetric, reverse-sawtooth-shaped MQW structure 100. FIG. 12A shows the conduction 120 and valence 130 bands of the unpolarized wells, which are asymmetric about a bandgap minimum at the left edge of the well 200. Alternatively, the non-linear upward grading may comprise multiple layers of different curvature and/or portions of linear grading, and alternatives thereto are non-limiting. The first quantum levels 210a, 210b and wavefunctions 220a, 220b for electrons and holes are also shown and can be seen to have excellent overlap. The overlap is less than complete, however, similar reasons given with respect to FIG. 7A.

FIG. 12B shows the reverse-sawtooth-shaped QWs 100 wherein polarization effects have been incorporated, according to the present invention. The upward non-linear grading of the left side of the well 200 causes a non-uniform, negative space charge, inducing a more positive curvature in the energy bands 120, 130. Conversely, the downward step of the right side of the well 200 causes a positive sheet charge, inducing a more positive kink in the energy bands 120, 130. The magnitude of the positive change in curvature varies with the slope of the grading, as previously discussed, while the magnitude of the positive kink is proportional to the magnitude of the step. Advantageously, the right side of the QW 200 formed by the step heterojunction does not tilt, thereby reducing the effect of the deformation of the energy bands 120, 130 on the wavefunction 220a, 220b shift. Nonetheless, the first quantum levels 210a, 210b and wavefunctions 220a, 220b for electrons and holes are also shown and can be seen to be shifted in opposite directions causing the magnitude of the overlap integral to be reduced. The conduction band 120 curvature becomes less negative causing the notch to become wider. As a result, the conduction band quantum level 210a drops in energy and the peak of the wavefunction 220a moves away from the nearest QW 200 interface. The valence band 130 curvature also becomes more positive causing the notch to sharpen causing the hole wavefunction 220b to move slightly toward the QW 200 interface. As a result, the valence band quantum level 210b decreases in energy moving away from the conduction band 120. Overall, however, the distance between the quantum levels 210a, 210b stays substantially the same or increases slightly, giving rise to a blue shift in the emission wavelength. Depending on the grading used, the overlap between electron 220a and hole 220b wavefunctions may remain substantially the same. Thus, the QCSE may be reduced for this band structure. This MQW band structure 100 may have the additional advantage of built-in electric fields in the valence band that encourage carrier drift from right to left thereby improving the hole distribution uniformity.

The meta-grading of the period or composition of the MQW structure 100 for the purpose of improving the hole distribution uniformity is also contemplated, according to the present invention. The period of a MQW structure may be measured along the growth direction from a first substrate-side QW interface to the next substrate-side QW interface. Either the period of the concatenated QWs 100 or the period of the QW/QB pairs may be varied, as, for example, being smaller on the n-side and larger on the A-side of the MQW structure 100 or vice versa. Such a non-uniform period may match the drift and/or diffusion profiles of the holes, thereby promoting distribution uniformity. For example, a non-uniform period for concatenated QWs may vary from a value of about 5 nm to about 15 nm. As used herein, the word “about” used in reference to a value means ±0.01 nm. When QBs are present, the period of the QW/QB pair may be varied by changing the thickness of the QW and/or QB. For example, the period of the QW/QB pair may vary from about 8 nm to about 20 nm wherein the thickness of the QB remains constant at 3 nm and the thickness of the QW varies from about 5 nm to about 17 nm. Alternatively, the period of the QW/QB pair may remain constant, while the ratio of the QW to QB thickness changes. For example, the period of the QW/QB pair may be 15 nm, while the QW thickness varies from about 5 nm to about 10 nm while the thickness of the QB simultaneously varies from about 10 nm to about 5 nm.

Regarding the composition, the bandgap range of the QWs or QW/QB combination may be varied, as, for example, being smaller on the n-side and larger on the p-side of the MQW structure 100 or vice versa. The bandgap range may be calculated as the maximum bandgap minus the minimum bandgap for each QW or QW/QB pair. Bandgap range variation can be realized by varying the minimum and/or maximum bandgap. Such composition grading may provide an overall internal electric field promoting hole drift from the p-side to the n-side, thereby promoting distribution uniformity. For example, in a non-uniform composition MQW structure, the minimum bandgap may vary from about 2.4 eV to about 2.6 eV in the growth direction while the maximum bandgap varies from about 3.0 eV to about 3.4 eV in the same direction, giving a bandgap range variation of 0.6 eV to 0.8 eV. As used herein, the word “about” used in reference to a value means ±1 meV. The III-N materials systems (AlN, GaN, InN, and ternary and quaternary alloys thereof) can produce bandgaps of between 0.65 and about 6.1 eV.

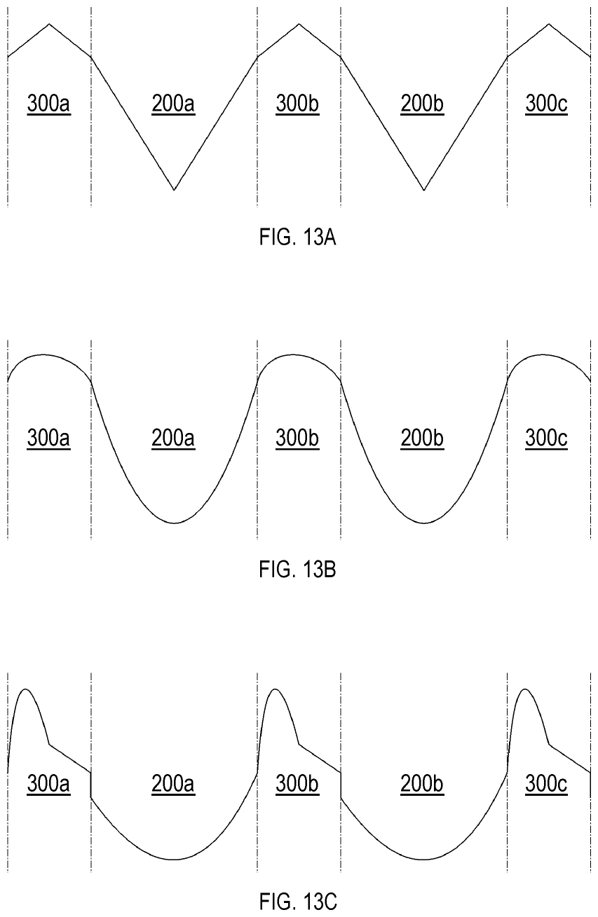

In an alternate but equivalent approach, continuously graded QWs 100 may be separated by continuously graded QBs 300, with no more than one interface between them being discontinuous, according to the present invention. The QWs 100 and/or QBs 300 may be symmetric or asymmetric. FIGS. 13A-130 give some examples of multiple QW/QB band structures with the interfaces indicated by dashed vertical lines. In FIG. 13A symmetric, linearly graded QWs 200a, 200b are separated by symmetric, linearly graded QBs 300a-300c. The interface between QWs 200a, 200b and QBs 300a-300c is kinked. In FIG. 13B symmetric, smoothly graded QWs 200a, 200b are separated by asymmetric, smoothly graded QBs 300a-300c. The interface between QW 200a and QB 300b is tangent while the interface between QB 300b and QW 200b is kinked. In FIG. 13C asymmetric, smoothly graded QWs 200a, 200b are separated by asymmetric, smoothly and linearly graded QBs 300a-300c. The interface between QW 200a and QB 300b is positively kinked while the interface between QB 300b and QW 200b includes a negative kink, a downward step, and a positive kink. Other combinations of these elements may be used without limitation. In all cases the well/barrier pair has no more than one discontinuous interface per well.

A QB 300 may be disposed between the n-type electron injection layer and the MQW 100 active region and between the MQW 100 active region and the p-type electron blocking layer and/or the p-type hole injection layer. However, other transition layers may be used without limitation, including identical or non-identical first and last QBs 300. Any type of transition layer between the MQW active are and the n- and p-type carrier injection layers, including the lack thereof, is contemplated herein.

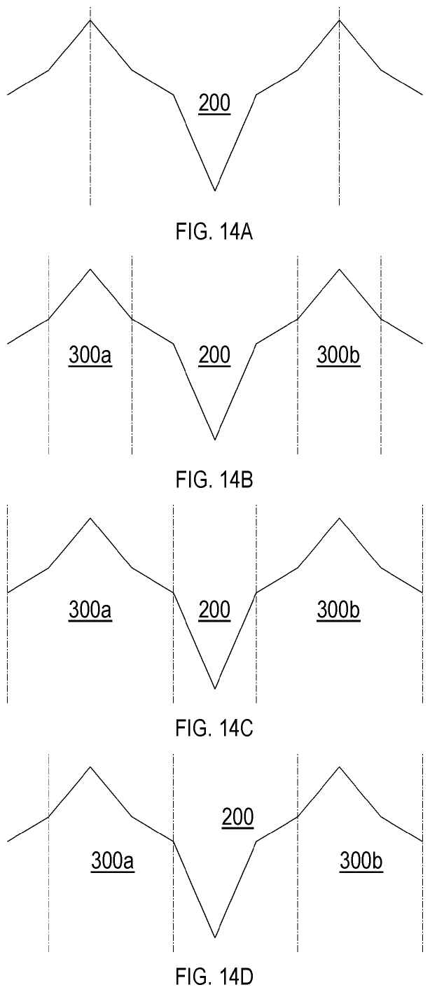

Barrier-free QWs 200 with more than two graded layers have been previously described, as, for example, in FIG. 8A, i.e., four layers, in light of FIG. 6A which describes two smoothly graded layers with an inflection point between them. Such QWs 200 may be symmetric or asymmetric. Whenever a QW 200 comprises more than one graded layer as defined herein, the possibility arises for interpretation of at least one layer as a QB 200 or sub-layer thereof. FIGS. 14A-140 demonstrate the various possible interpretations of an exemplary multi-layer, linearly graded MQW structure 100, according to the present invention. It is helpful to recall that the QW layers must include the bandgap minimum, and the QB layers, if present, must include the bandgap maximum. In the figures, the vertical dashed lines delineate the QW/QB interfaces. In FIG. 14A, the band structure may be interpreted as a plurality of symmetric, barrier-free, concatenated QWs 200 with additional wells to the left and right, which are partially shown. In FIG. 14B, the same band structure may be interpreted as a four-layer, linearly graded, symmetric QW 200 sandwiched by a pair of two-layer, linearly graded QBs 300a, 300b. In this case there are both positive and negative kinks within the QW 200. In FIG. 14C, a symmetric V-well 200 is flanked by a pair of four-layer, linearly graded QBs 300a, 300b. Note that there are both positive and negative kinks within the barrier. In FIG. 14D, the same band structure may be interpreted as a three-layer, linearly graded, asymmetric QW 200 bookended by a pair of three-layer, linearly graded, asymmetric QBs 300a, 300b. In this case positive and negative kinks are present in both the QW 200 and QBs 300a, 300b. The same interpretation possibilities apply to non-linearly graded layers or a combination of linearly and non-linearly graded layers.

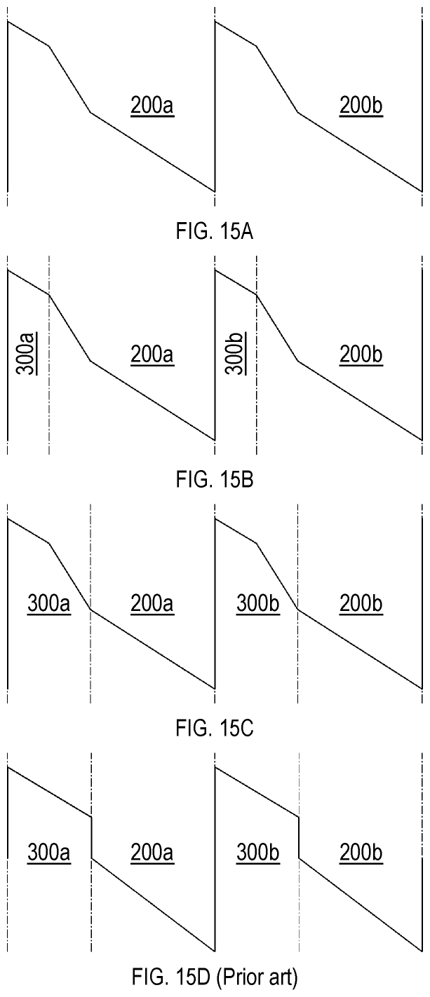

Another example of QW/QB interpretation may be viewed in FIGS. 15A-150, which show an asymmetric, multi-layer, linearly graded sawtooth MQW band structure 100, according to the present invention. In FIG. 15A, the band structure may be interpreted as a plurality of an asymmetric, multi-layer, linearly graded sawtooth QWs 100. In FIG. 14B, the same band structure may be interpreted as a two-layer, linearly graded, asymmetric QW 200a sandwiched by a pair of single-layer, linearly graded QBs 300a, 300b. In FIG. 14C, the same band structure may be interpreted as a single-layer, linearly graded, asymmetric QW 200a sandwiched by a pair of two-layer, linearly graded QBs 300a, 300b. In summary, any continuously graded, periodic band structure, that is, one without constant bandgap portions, may be interpreted as either concatenated QWs 100, 200, concatenated QBs 300, or a combination of continuously graded QW/QB pairs with no more than one discontinuous interface per pair and is within the scope of this disclosure. Note that adding a second discontinuous interface, as shown in FIG. 15D, produces a more conventional graded QW/graded QB pair, and is outside the scope of this disclosure.

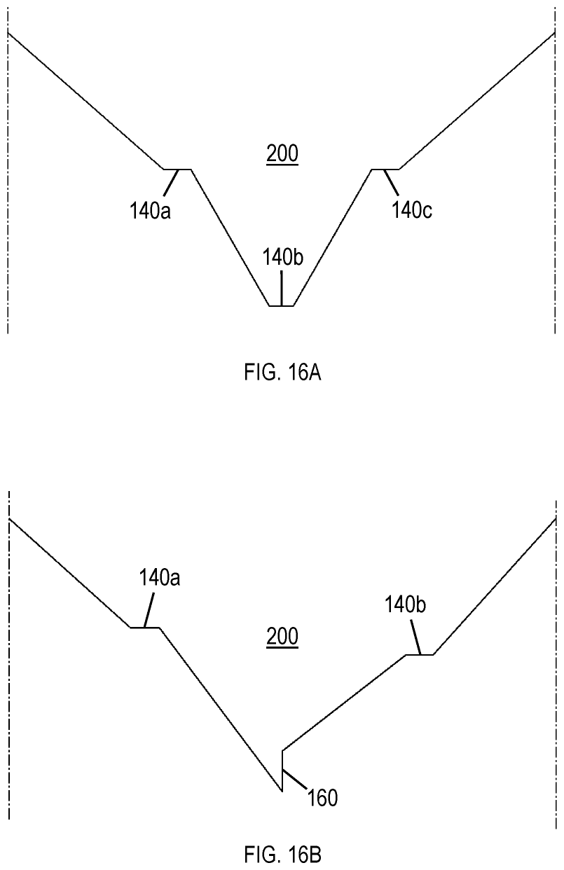

While the full benefit of the disclosed MQW band structure 100 is best realized with all layers continuously graded, small deviations from the ideal, in the form of a thin constant bandgap (CB) 140 layer or small step heterojunctions, can still achieve some performance improvement relative to ungraded QWs 200. In these embodiments the band structure of the QWs 200 changes from strictly increasing to monotonically increasing. The distinction is important because the former specifically precludes CB layers 140 in the QW 200. FIGS. 16A-16B provides some examples of small perturbations that may be allowed and still improve the wavefunction overlap. FIG. 16A shows a symmetric V-shaped well 200a with three thin CB layers 140a-140c. FIG. 16B shows an asymmetric V-shaped well 200b with two thin CB layers 140a, 140b and one small step heterojunction 160. If the thickness of any one CB layer 140 is small enough relative to the total thickness of the QW 200, band bending and kinking will add only a small perturbation to the wavefunctions and still allow for an improved overlap. For example, if the total thickness of the QW is 15 nm, then a 1.5 nm CB layer (about 4 to 5 monolayers) would induce an acceptable perturbation. Multiple CB layers 140a, 140b may be interspersed throughout the QW 200b, provided the total thickness of such layers is no greater than about 20% of the total QW thickness, or 3 nm according to the previous example.

The previous description of the disclosed embodiments is provided to enable any person skilled in the art to make or use the invention. Various modifications to these embodiments will be readily apparent to those skilled in the art, and the generic principles defined herein can be applied to other embodiments without departing from the spirit or scope of the invention. It is therefore desired that the present embodiments be considered in all respects as illustrative and not restrictive, reference being made to the appended claims as well as the foregoing descriptions to indicate the scope of the invention.

What is claimed is:

1. A light-emitting device comprising:
an n-type semiconductor layer disposed on a substrate;
an active region disposed on the n-type semiconductor layer, the active region comprising: a plurality of concatenated quantum wells, each concatenated quantum well having an energy band structure comprising:
a strictly increasing bandgap extending from a minimum value to a maximum value; and
no more than one bandgap discontinuity per concatenated quantum well; and
a p-type semiconductor layer disposed on the active region.

2. The light-emitting device of claim 1, wherein each concatenated quantum well of said plurality of concatenated quantum wells comprises a period varying between about 5 nm and about 20 nm, and wherein at least one concatenated quantum well has a non-uniform period with respect to at least one other period.

3. The light-emitting device of claim 1, wherein each concatenated quantum well of said plurality of concatenated quantum wells comprises a bandgap range varying between about 0.1 eV and about 3.5 eV, and wherein at least one concatenated quantum well has a non-uniform bandgap range with respect to at least one other bandgap range.

4. A light-emitting device comprising:
an n-type semiconductor layer disposed on a substrate;
an active region disposed on the n-type semiconductor layer, the active region comprising:
a plurality of quantum wells, each quantum well comprising a strictly increasing bandgap that increases from a minimum value;
a quantum barrier separating each quantum well, each of said quantum barriers comprising a strictly decreasing bandgap that decreases from a maximum value; and
an interface coupling the strictly increasing bandgap and the strictly decreasing bandgap forming an energy band;
wherein the energy band at no more than one interface per quantum well is discontinuous; and
a p-type semiconductor layer disposed on the active region.

5. The light-emitting device of claim 4, wherein each quantum well and adjacent quantum barrier comprises a period varying between about 5 nm and about 25 nm, and wherein at least one quantum well and adjacent quantum barrier has a non-uniform period with respect to at least one other period.

6. The light-emitting device of claim 4, wherein each quantum well and adjacent quantum barrier comprises a quantum well thickness to quantum barrier thickness ratio varying between about 0.05 and about 0.95, and wherein at least one quantum well and adjacent quantum barrier has a non-equal ratio with respect to at least one other ratio.

7. The light-emitting device of claim 4, wherein each quantum well and adjacent quantum barrier comprises a bandgap range varying between about 0.1 eV and about 3.5 eV, and wherein at least one quantum well and adjacent quantum barrier have a non-uniform bandgap range with respect to at least one other bandgap range.

8. The light-emitting device of claim 4, wherein one of said quantum barriers is disposed between the plurality of quantum wells and quantum barriers and the n-type semiconductor layer and/or the p-type semiconductor layer.

9. A light-emitting device comprising:
an n-type semiconductor layer disposed on a substrate;
an active region disposed on the n-type semiconductor layer, the active region comprising:
a plurality of concatenated quantum wells, each concatenated quantum well comprising:
a total thickness, and
an energy band structure comprising
a monotonically increasing bandgap extending from a minimum value to a maximum value, and
no more than one bandgap discontinuity, and
at least one constant bandgap portion,
wherein, for each concatenated quantum well, no constant bandgap portion of the energy band structure comprises more than 10% of the total thickness,
and wherein, for each concatenated quantum well, the sum of thicknesses of all constant bandgap portions comprises no more than 20% of the total thickness; and
a p-type semiconductor layer disposed on the active region.

10. The light-emitting device of claim 9, wherein each concatenated quantum well of said plurality of concatenated quantum wells comprises a period varying between about 5 nm and about 20 nm, and wherein at least one concatenated quantum well has a non-uniform period with respect to at least one other period.

11. The light-emitting device of claim 9, wherein each concatenated quantum well of said plurality of concatenated quantum wells comprises a bandgap range varying between about 0.1 eV and about 3.5 eV, and wherein at least one concatenated quantum well has a non-uniform bandgap range with respect to at least one other bandgap range.
